(19) United States
(12) Patent Application Publication
(10) Pub. No.: US 2025/0233015 A1
(43) Pub. Date: Jul. 17, 2025

(54) METHODS OF MANUFACTURING INTERCONNECT STRUCTURES

(71) Applicant: Applied Materials, Inc., Santa Clara, CA (US)

(72) Inventors: Bhaskar Jyoti Bhuyan, San Jose, CA (US); Lisa J. Enman, Sunnyvale, CA (US); Feng Q. Liu, San Jose, CA (US); Jeffrey W. Anthis, Redwood City, CA (US); Mark Saly, Santa Clara, CA (US); Lakmal C. Kalutarage, San Jose, CA (US); Aaron Dangerfield, San Jose, CA (US); Jesus Candelario Mendoza-Gutierrez, San Jose, CA (US); Sze Chieh Tan, Singapore (SG)

(73) Assignee: Applied Materials, Inc., Santa Clara, CA (US)

(21) Appl. No.: 19/019,830

(22) Filed: Jan. 14, 2025

Related U.S. Application Data
(60) Provisional application No. 63/620,923, filed on Jan. 15, 2024.

(51) Int. Cl. H01L 21/768

(52) U.S. Cl. CPC H01L 21/76831; H01L 21/76846; H01L 21/76877

(57) ABSTRACT

Methods of manufacturing interconnect structures as part of a microelectronic device fabrication process are described. The methods include forming a dielectric layer including at least one feature defining a gap having sidewalls and a bottom on a substrate. The methods further include forming a blocking layer on the bottom by exposing the substrate to a blocking compound; selectively depositing a barrier layer on the sidewalls; selectively depositing a metal liner on the barrier layer on the sidewalls; removing the blocking layer; and performing a gap fill process to fill the gap with a gapfill material.

### CROSS-REFERENCE TO RELATED APPLICATIONS

This application claims priority to U.S. Provisional Application No. 63/620,923, filed Jan. 15, 2024, the entire disclosure of which is hereby incorporated by reference herein.

### TECHNICAL FIELD

Embodiments of the disclosure generally relate to methods of manufacturing interconnect structures in the manufacture of microelectronic devices. More particularly, embodiments of the disclosure are directed to blocking chemistries for selective deposition of a barrier layer and a metal liner.

### BACKGROUND

Multiple challenges impede power and performance improvements when scaling transistors and interconnects to the 3 nm node, 2 nm node, 1.4 nm node, and beyond. Interconnects include metal lines that transfer current within the same device layer and metal vias that transfer current between layers. Pitch reduction narrows the width of both and increases resistance, and also increases the voltage drop across a circuit, throttling circuit speed and increasing power dissipation.

While transistor performance improves with scaling, the same cannot be said for interconnect metals. As dimensions shrink, interconnect via resistance can increase by a factor of 10. An increase in interconnect via resistance may result in resistive-capacitive (RC) delays that reduce performance and increases power consumption. A conventional copper interconnect structure includes a barrier layer and/or a metal liner deposited on the sidewalls of a gap that provide a via, the sidewalls made of a dielectric material, providing good adhesion and preventing the copper from diffusing into the dielectric layer. Barrier layers can typically be the largest contributor to via resistance due to high resistivity. Past approaches have focused on reducing the thickness of barrier layers or finding barrier layers with lower resistivity to decrease via resistance. Increased via resistance remains an issue, especially in smaller features when barrier layers on sidewalls form an increasing percentage of the via volume.

One approach has been to block or decrease the thickness of the barrier layer on the metal surface at the bottom of the via while the thickness on the dielectric surface at the sidewalls remains. Since the barrier properties of the barrier layer are required between the metal surface and the dielectric surface, this approach allows for the barrier layer to remain intact, but the reduced thickness on the metal surface improves via resistance. These processes are referred to as selective deposition processes.

Selective deposition of materials can be accomplished in a variety of ways. A chemical precursor may react selectively with one surface relative to another surface (e.g., metallic or dielectric). Process parameters such as pressure, substrate temperature, precursor partial pressures, and/or gas flows can be tuned to modulate the chemical kinetics of a particular surface reaction. Another possible scheme involves surface pretreatments that can be used to activate or deactivate a surface of interest to an incoming deposition precursor. Typically, selective deposition refers to the deposition of a layer on a metallic surface. A reverse selective deposition process deposits a layer on the dielectric surface rather than the metallic surface.

In current interconnect manufacturing processes, a metal liner deposited on a barrier layer adheres to the barrier layer and facilitates subsequent copper fill in the gap between the sidewalls. Current approaches focus on selectively growing a metal liner on a via sidewall relative to the via bottom with high selectivity in attempt to reduce via resistance and copper corrosion, though selective growth remains a challenge.

One of the key challenges of organic blocking compounds, for example, is surface contamination after the blocking layer removal step. Due to presence of metal-carbon, metal-nitrogen, and/or metal-oxygen bonding, a layer of organic contaminants may remain on the bottom metal surface, which can be a failure point in electrical tests.

Accordingly, there is a need for methods for depositing material layers that improve performance of interconnects, for example, reducing via resistance and improving deposition selectivity. There is also a need for blocking chemistries that have reduced electrical penalty compared to blocking compounds that leave a layer of organic contaminants on the bottom metal surface.

### SUMMARY

One or more embodiments of the disclosure are directed to methods of manufacturing microelectronic devices. In one or more embodiments, the methods comprise forming a dielectric layer on a substrate. The dielectric layer includes at least one feature defining a gap having sidewalls and a bottom. In one or more embodiments, the methods comprise forming a blocking layer on the bottom by exposing the substrate to a blocking compound. The blocking compound has a formula of MXyLz, wherein M is a metal selected from the group consisting of ruthenium (Ru), molybdenum (Mo), tungsten (W), copper (Cu), cobalt (Co), nickel (Ni), iridium (Ir), platinum (Pt), palladium (Pd), and osmium (Os), X comprises one or more of substituted or unsubstituted cyclopentadiene, substituted or unsubstituted benzene, substituted or unsubstituted cyclohexadiene, substituted or unsubstituted cycloheptadiene, or substituted or unsubstituted cyclooctadiene, L is a carbon-containing functional group, y is an integer in a range of from 0 to 6, and z is an integer in a range of from 0 to 6. In one or more embodiments, the methods comprise: selectively depositing a barrier layer on the sidewalls; selectively depositing a metal liner on the barrier layer on the sidewalls; removing the blocking layer; and performing a gap fill process to fill the gap.

Additional embodiments of the disclosure are directed to methods of manufacturing microelectronic devices. In one or more embodiments, the methods comprise forming a dielectric layer on a substrate. The dielectric layer includes at least one feature defining a gap having sidewalls and a bottom. In one or more embodiments, the methods comprise forming a first blocking layer on the bottom by exposing the substrate to a first blocking compound. In one or more embodiments, the methods comprise selectively depositing a barrier layer comprising tantalum nitride (TaN) on the sidewalls; removing the first blocking layer; forming a second blocking layer on the bottom by exposing the substrate to a second blocking compound; selectively depositing a metal liner comprising a single layer of ruthenium (Ru) or a multilayer film having a first liner layer comprised of ruthenium (Ru) and a second liner layer comprised of cobalt (Co) on the barrier layer on the sidewalls; removing the second blocking layer; and performing a gap fill process comprising filling the gap with a gapfill material comprising one or more of copper (Cu) or cobalt (Co). Each of the first blocking compound and the second blocking compound independently have a formula of MX_{y}L_{z}, wherein M is a metal selected from the group consisting of ruthenium (Ru), molybdenum (Mo), tungsten (W), copper (Cu), cobalt (Co), nickel (Ni), iridium (Ir), platinum (Pt), palladium (Pd), and osmium (Os), X comprises one or more of substituted or unsubstituted cyclopentadiene, substituted or unsubstituted benzene, substituted or unsubstituted cyclohexadiene, substituted or unsubstituted cycloheptadiene, or substituted or unsubstituted cyclooctadiene, L is a carbon-containing functional group, y is an integer in a range of from 0 to 6, and z is an integer in a range of from 0 to 6.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A illustrates a process flow diagram of a method of manufacturing a microelectronic device in accordance with one or more embodiments of the disclosure;

FIG. 1B illustrates a cross-sectional schematic view of a microelectronic device including a gap having sidewalls and a bottom with a blocking layer formed on the bottom of the gap in accordance with one or more embodiments of the disclosure;

FIG. 1C illustrates a barrier layer selectively deposited on the sidewalls of the gap of FIG. 1B in accordance with one or more embodiments of the disclosure;

FIG. 1D illustrates a metal liner selectively deposited on the barrier layer of FIG. 1C in accordance with one or more embodiments of the disclosure;

FIG. 1E illustrates removal of the blocking layer formed in FIG. 1B in accordance with one or more embodiments of the disclosure;

FIG. 1F illustrates a gap fill process filling the gap of FIG. 1B in accordance with one or more embodiments of the disclosure;

FIG. 2A illustrates a process flow diagram of a method of manufacturing a microelectronic device in accordance with one or more embodiments of the disclosure;

FIG. 2B illustrates a cross-sectional schematic view of a microelectronic device including a gap having sidewalls and a bottom with a first blocking layer formed on the bottom of the gap in accordance with one or more embodiments of the disclosure;

FIG. 2C illustrates a barrier layer selectively deposited on the sidewalls of the gap of FIG. 2B in accordance with one or more embodiments of the disclosure;

FIG. 2D illustrates removal of the first blocking layer formed in FIG. 2B in accordance with one or more embodiments of the disclosure;

FIG. 2E illustrates a second blocking layer formed on the bottom of the gap in accordance with one or more embodiments of the disclosure;

FIG. 2F illustrates a metal liner selectively deposited on the barrier layer in accordance with one or more embodiments of the disclosure;

FIG. 2G illustrates removal of the second blocking layer in accordance with one or more embodiments of the disclosure; and

FIG. 2H illustrates a gap fill process filling the gap of FIG. 2A in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Spatially relative terms, such as “beneath,” “below,” “lower,” “above,” “upper” and the like, may be used herein for ease of description to describe one element's relationship to another element(s) or feature(s) as illustrated in the Figures. It will be understood that the spatially relative terms are intended to encompass different orientations of the microelectronic device in use or operation in addition to the orientation depicted in the Figures. For example, if the microelectronic device in the Figures is turned over, elements described as “below” or “beneath” other elements would then be oriented “above” the other elements. Thus, the exemplary term “below” may encompass both an orientation of above and below. The microelectronic device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in some embodiments,” “in one embodiment,” or “in an embodiment” in various places throughout this specification are not necessarily referring to the same embodiment of the disclosure. In one or more embodiments, the particular features, structures, materials, or characteristics are combined in any suitable manner.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to “depositing on” or “forming on” a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. In some embodiments, the semiconductor substrate comprises one or more of doped or undoped crystalline silicon (Si), doped or undoped crystalline silicon germanium (SiGe), doped or undoped amorphous silicon (Si), or doped or undoped amorphous silicon germanium (SiGe). Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used herein, the terms “precursor,” “reactant,” “reactive gas,” “reactive species,” and the like are used interchangeably to refer to any gaseous species that can react with the substrate surface.

Sputtering is a physical vapor deposition (PVD) process in which high-energy ions impact and erode a solid target and deposit the target material on the surface of a substrate, such as a semiconductor substrate. In semiconductor fabrication, the sputtering process is usually accomplished within a semiconductor fabrication chamber also known as a PVD processing chamber or a sputtering chamber. Sputtering has long been used for the deposition of metals and related materials in the fabrication of semiconductor integrated circuits.

Typically, the sputtering chamber comprises an enclosure wall that encloses a process zone into which a process gas is introduced, a gas energizer to energize the process gas, and an exhaust port to exhaust and control the pressure of the process gas in the chamber. The chamber is used to sputter deposit a material from a sputtering target onto the semiconductor substrate. In the sputtering processes, the sputtering target is bombarded by energetic ions, such as a plasma, causing material to be knocked off the target and deposited as a film on the semiconductor substrate.

A typical semiconductor fabrication chamber has a target assembly including disc-shaped target of solid metal or other material supported by a backing plate that holds the target. To promote uniform deposition, the PVD chamber may have an annular concentric metallic ring, which is often called a shield, circumferentially surrounding the disc-shaped target.

Plasma sputtering may be accomplished using either DC sputtering or RF sputtering. Plasma sputtering typically includes a magnetron positioned at the back of a sputtering target including two magnets of opposing poles magnetically coupled at their back through a magnetic yoke to project a magnetic field into the processing space to increase the density of the plasma and enhance the sputtering rate from a front face of the target. Magnets used in the magnetron are typically closed loop for DC sputtering and open loop for RF sputtering.

As used herein, the term “chemical vapor deposition” refers to the exposure of at least one reactive species to deposit a layer of material on the substrate surface. In some embodiments, the chemical vapor deposition (CVD) process comprises mixing the two or more reactive species in the processing chamber to allow gas phase reactions of the reactive species and deposition. In some embodiments, the CVD process comprises exposing the substrate surface to two or more reactive species simultaneously. In some embodiments, the CVD process comprises exposing the substrate surface to a first reactive species continuously with an intermittent exposure to a second reactive species. In some embodiments, the substrate surface undergoes the CVD reaction to deposit a layer having a predetermined thickness. In the CVD process, the layer can be deposited in one exposure to the mixed reactive species or can be multiple exposures to the mixed reactive species with purges between. In some embodiments, the substrate surface is exposed to the first reactive species and the second reactive species substantially simultaneously.

As used herein, “substantially simultaneously” means that most of the duration of the first reactive species exposure overlaps with the second reactive species exposure.

As used herein, the term “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive species is purged from the reaction chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive species.

“Cyclical deposition” or “atomic layer deposition” (ALD) refers to the sequential exposure of two or more reactive species to deposit a layer of material on a substrate surface. The substrate, or portion of the substrate, is exposed separately to the two or more reactive species which are introduced into a reaction zone of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially. In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive species or reaction by-products from the reaction zone. Alternatively, the purge gas may flow continuously throughout the deposition process so that only the purge gas flows during the time delay between pulses of reactive species. The reactive species are alternatively pulsed until a desired layer or layer thickness is formed on the substrate surface. In either scenario, the ALD process of pulsing compound A, purge gas, compound B and purge gas is a cycle. A cycle can start with either compound A or compound B and continue the respective order of the cycle until achieving a layer with the predetermined thickness.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

Some embodiments of the disclosure provide methods for improving performance of interconnects. Interconnects comprise metal lines that transfer current within the same device layer, and metal vias that transfer current between layers. These lines and vias are formed with a conductive metal such as copper (Cu) or cobalt (Co) in gaps formed within the microelectronic device. In one or more embodiments, a dielectric layer comprises at least one feature defining a gap having sidewalls and a bottom. In one or more embodiments, the gap includes the metal lines and the metal vias. In one or more embodiments, the metal lines have a sidewall and a bottom. In one or more embodiments, the metal vias have a sidewall and a bottom. As used in this specification and the appended claims, unless specified otherwise, reference to the “bottom of the gap” is intended to mean the bottom of the metal via, which is nearest the substrate surface.

Embodiments of the disclosure provide methods of manufacturing interconnect structures in the manufacture of microelectronic devices. In one or more embodiments, the microelectronic devices described herein comprise at least one top interconnect structure that is interconnected to at least one bottom interconnect structure. Embodiments of the disclosure provide microelectronic devices and methods of manufacturing microelectronic devices that improve performance of interconnects, for example, reducing via resistance.

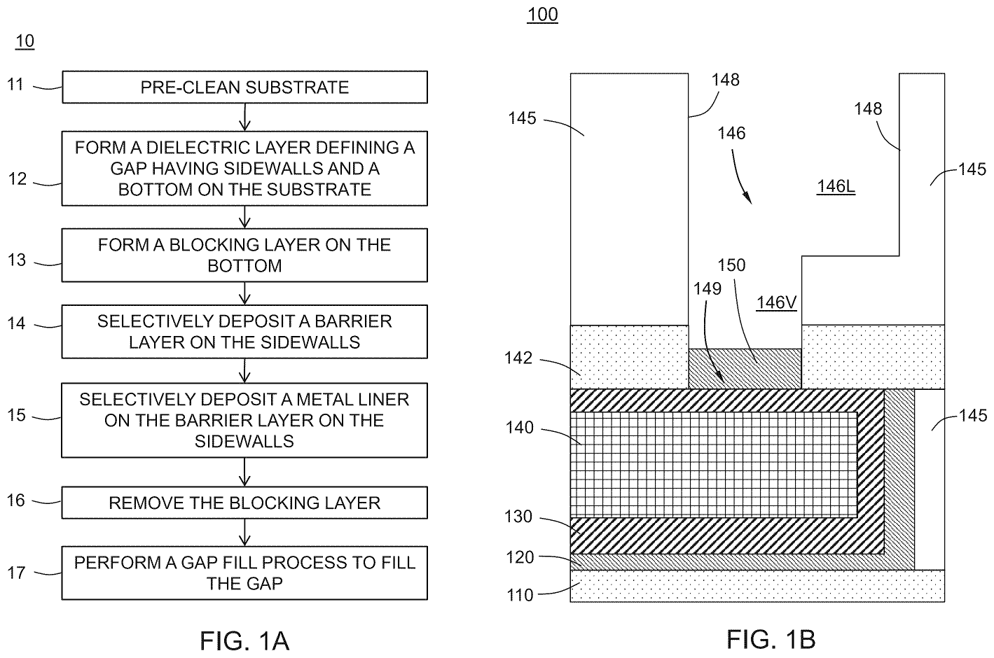

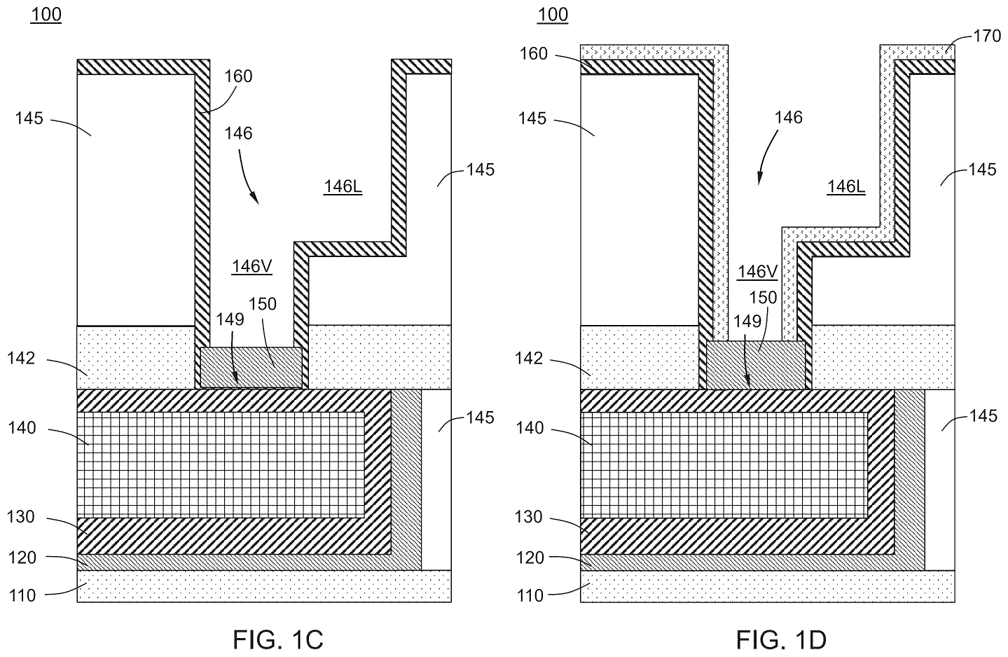

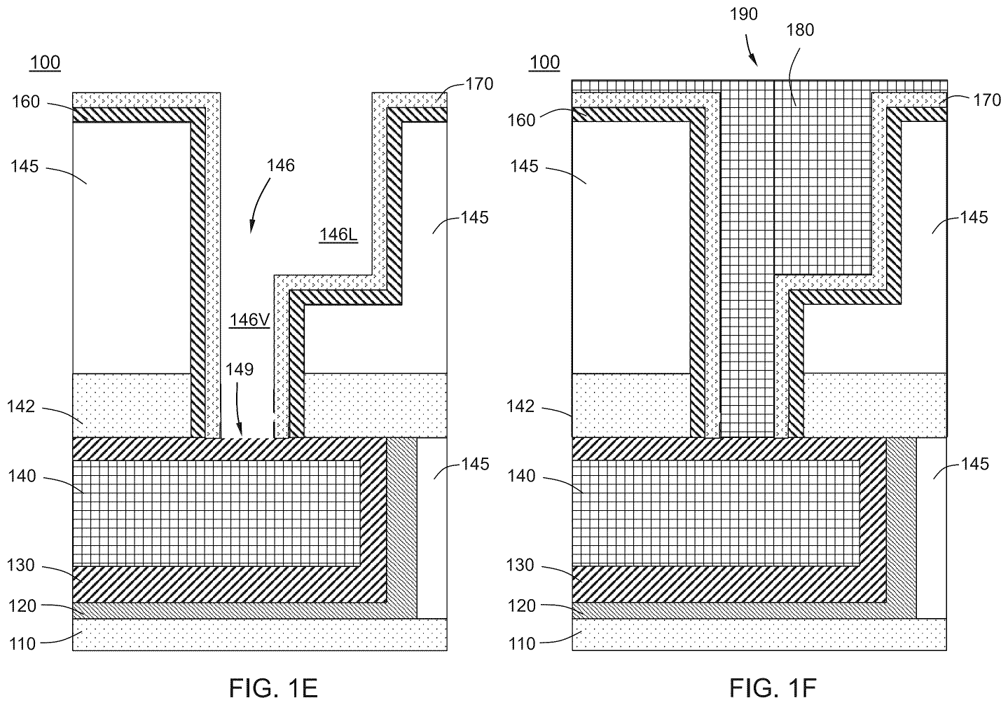

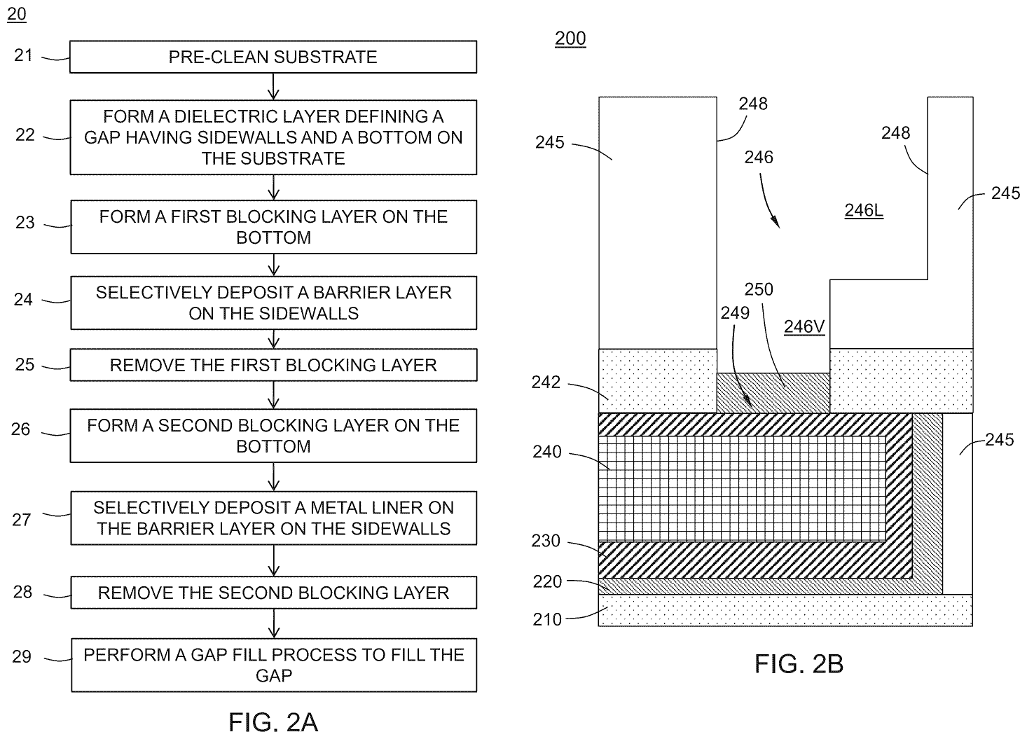

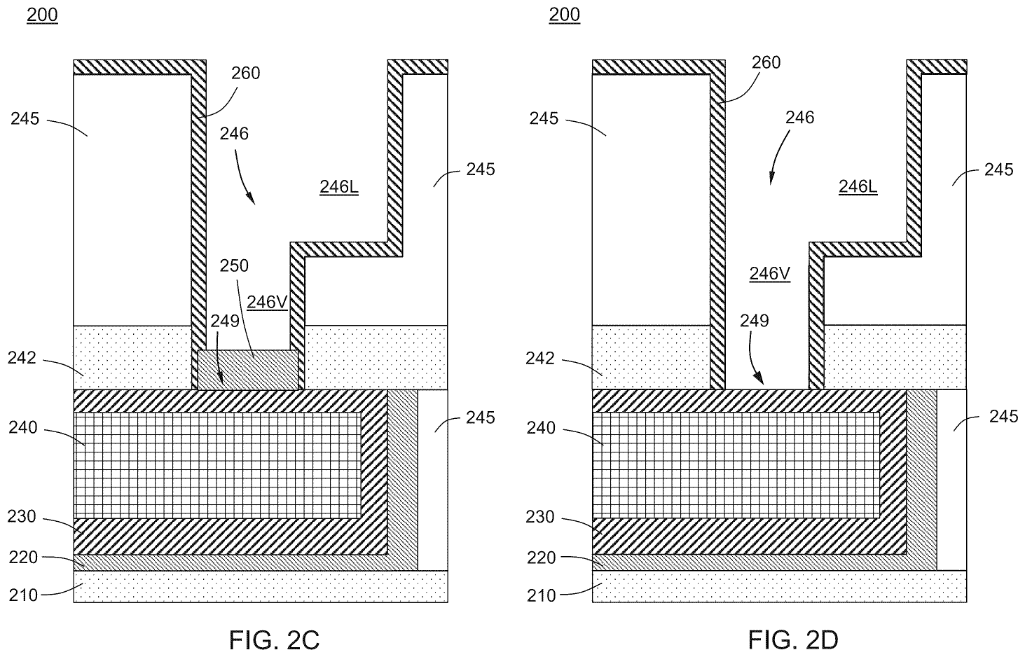

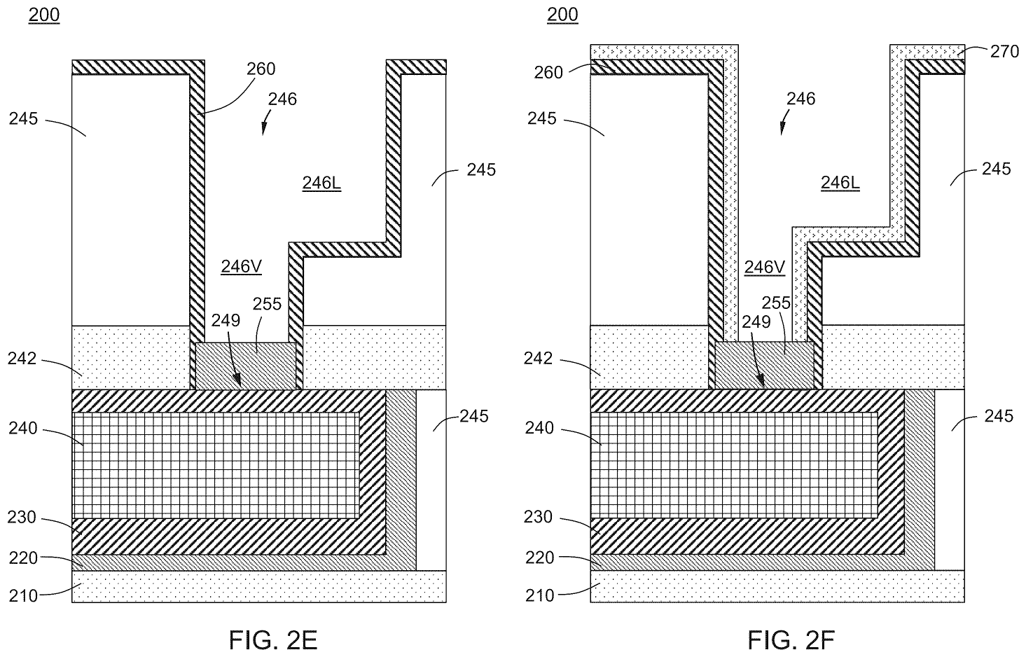

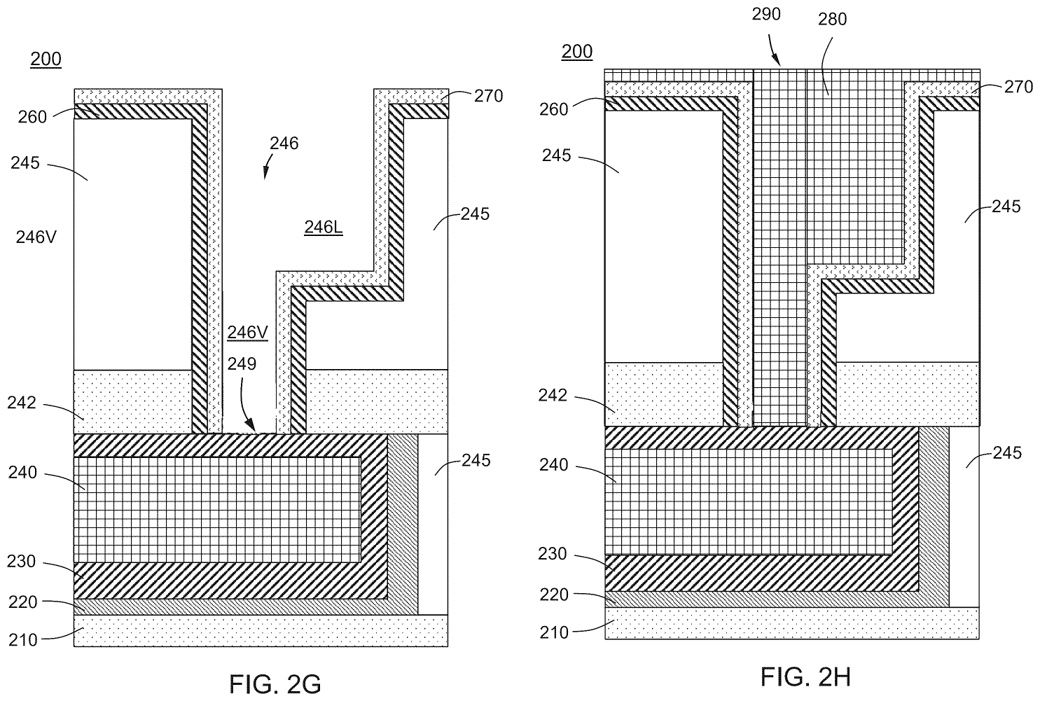

Methods of manufacturing microelectronic devices are described herein with reference to FIGS. 1A-1F and FIGS. 2A-2H. FIG. 1A is a process flow diagram of an exemplary method 10 of manufacturing a microelectronic device 100. FIGS. 1B-1F illustrate stages of manufacture of the microelectronic device 100 during the method 10. FIG. 2A is a process flow diagram of an exemplary method 20 of manufacturing a microelectronic device 200. FIGS. 2B-2H illustrate stages of manufacture of the microelectronic device 200 during the method 20.

The methods, e.g., method 10 and method 20, generally refer to methods of manufacturing microelectronic devices and more particularly refer to methods of manufacturing interconnect structures as part of a microelectronic device fabrication process. Accordingly, it will be appreciated by the skilled artisan that one or more additional operations needed to complete the fabrication of a microelectronic device are known to the skilled artisan and are within the scope of the present disclosure without undue experimentation.

Referring to FIG. 1A, the method 10 comprises, at operation 11, pre-cleaning a substrate 110. In one or more embodiments, keeping the pre-cleaning process under vacuum ensures that no oxide is introduced/formed on the substrate 110 during the method 10. At operation 11, pre-cleaning the substrate 110 removes native oxides from the surface of the substrate 110.

The pre-cleaning process of operation 11 can be any suitable process. In some embodiments, the pre-cleaning process of operation 11 removes polymeric residues and copper oxide from the interconnect and maintains the integrity of the dielectric surface. As used herein, the term “substrate 110” can be used to refer to a substrate and/or a pre-cleaned substrate, unless the context clearly indicates otherwise.

At operation 12, the method 10 comprises forming a dielectric layer on the substrate 110, e.g., the pre-cleaned substrate. The dielectric layer 145 comprises at least one feature defining a gap 146 having sidewalls 148 and a bottom 149. At operation 13, the method 10 comprises forming a blocking layer 150 on the bottom 149 by exposing the substrate 110 to a blocking compound. At operation 14, the method 10 comprises selectively depositing a barrier layer 160 on the sidewalls 148. At operation 15, the method 10 comprises selectively depositing a metal liner 170 on the barrier layer 160. At operation 16, the method 10 comprises removing the blocking layer 150. At operation 17, the method 10 comprises performing a gap fill process to fill the gap 146.

In one or more embodiments, the method 10 comprises operation 11, operation 12, operation 13, operation 14, operation 15, operation 16, and operation 17. In one or more embodiments, the method 10 consists essentially of operation 11, operation 12, operation 13, operation 14, operation 15, operation 16, and operation 17. In one or more embodiments, the method 10 consists of operation 11, operation 12, operation 13, operation 14, operation 15, operation 16, and operation 17. In one or more embodiments, the method 10 consists of operation 13 (where the dielectric layer 145 on the substrate 110, e.g., a pre-cleaned substrate, is provided), operation 14, operation 15, operation 16, and operation 17.

Referring to FIGS. 11B-1F, a portion of the microelectronic device 100 is shown during stages of manufacture. In FIG. 1B, the microelectronic device 100 comprises the substrate 110, a barrier layer 120 on the substrate 110, a metal layer 130 on the barrier layer 120, a conductive filled gap 140, an aluminum oxide etch stop layer 142, and the dielectric layer 145 on the aluminum oxide etch stop layer 142. The dielectric layer 145 comprises at least one feature defining the gap 146 having sidewalls 148 and the bottom 149. According to one or more embodiments, a blocking layer 150 is formed on the bottom 149 of the gap 146. It will be appreciated that in one or more embodiments, the conductive filled gap 140 forms a metal line that transfers current within the same device layer.

In one or more embodiments, the substrate 110 is a wafer, for example, a semiconductor substrate. In one or more embodiments, the substrate 110 is an etch stop layer on a wafer. In one or more embodiments, the substrate 110 is an aluminum oxide etch stop layer on a wafer.

In one or more embodiments, the barrier layer 120 comprises tantalum nitride (TaN). In one or more embodiments, the barrier layer 120 comprises tantalum nitride (TaN) formed by ALD.

In one or more embodiments, the metal layer 130 comprises one or more of ruthenium (Ru), copper (Cu), cobalt (cobalt), molybdenum (Mo), tantalum (Ta), or tungsten (W). In one or more embodiments, the metal layer 130 comprises one or more of copper (Cu), cobalt (cobalt), molybdenum (Mo), or tungsten (W). In one or more embodiments, a portion of the metal layer 130 is etched. In one or more embodiments, the blocking layer 150 is deposited on the portion of the metal layer 130 that is etched. In one or more embodiments, the conductive filled gap 140 comprises one or more of copper (Cu) or cobalt (Co). In one or more embodiments, the etch stop layer 142 comprises one or more of aluminum oxide, silicon nitride, or aluminum nitride.

In one or more embodiments, the dielectric layer 145 comprises a low-K dielectric material. In one or more embodiments, the dielectric layer 145 comprises silicon oxide (SiO). In one or more embodiments, the dielectric layer 145 comprises SiOₓH_{y}(CH_{z}). Further embodiments provide that the dielectric layer 145 comprises porous or carbon-doped SiOₓ. In some embodiments, the dielectric layer 145 is a porous or carbon-doped SiOₓ layer with a K value less than about 5. In other embodiments, the dielectric layer 145 is a multilayer structure. For example, in one or more embodiments, the dielectric layer 145 comprises a multilayer structure having one or more of a dielectric layer, an etch stop layer, and a hard mask layer.

In one or more illustrated embodiments, the dielectric layer 145 comprises at least one feature defining the gap 146 having sidewalls 148 and the bottom 149. The Figures show substrates 110 having a single feature for illustrative purposes; however, those skilled in the art will understand that there can be more than one feature.

As used herein, the term “feature” means any intentional surface irregularity. Suitable examples of features include but are not limited to trenches which have a top, two sidewalls and a bottom, peaks which have a top and two sidewalls. Features can have any suitable aspect ratio (ratio of the depth of the feature to the width of the feature). In some embodiments, the aspect ratio is greater than or equal to about 5:1, 10:1, 15:1, 20:1, 25:1, 30:1, 35:1 or 40:1.

In some embodiments, the at least one feature defines a cylindrical via that, when filled with metal, transfers current between layers, and lines that transfer current within the same device layer. In some embodiments, the at least one feature defines the gap 146 in the dielectric layer 145. In some embodiments, the gap 146 defines a via portion 146V and a line portion 146L.

The bottom 149 of the gap 146 is defined by the metal layer 130. In one or more embodiments, the bottom 149 of the gap 146 and the metal layer 130 comprise the same material. In one or more embodiments, the bottom 149 of the gap 146 comprises one or more of ruthenium (Ru), copper (Cu), cobalt (cobalt), molybdenum (Mo), tantalum (Ta), or tungsten (W). In one or more embodiments, the bottom 149 of the gap 146 comprises one or more of copper (Cu), cobalt (cobalt), molybdenum (Mo), or tungsten (W).

In one or more embodiments, the blocking layer 150 is formed on the bottom 149 of the gap 146 in accordance with operation 13 of the method 10 (FIGS. 1A and 1B). Stated differently, in one or more embodiments, the blocking layer 150 is formed on the metal layer 130, which defines the bottom 149 of the gap 146. In one or more embodiments, the portion of the metal layer 130 on which the blocking layer 150 is formed defines the bottom 149 of the gap 146. In one or more embodiments, the blocking layer 150 is formed selectively on the bottom 149 of the gap 146 by exposing the substrate 110 to a blocking compound.

Embodiments of the present disclosure employ blocking compounds that can be used to form a blocking layer on a surface to suppress or prevent subsequent deposition on that surface. It has been advantageously found that metallic blocking compounds, which will be described in further detail herein, can be used to suppress or prevent subsequent deposition on a metallic surface, e.g., metal lines.

As used herein, the blocking compounds may be used in one or more of “selective barrier applications” or “selective liner applications” as part of the disclosed methods of manufacturing interconnect structures in the manufacture of microelectronic devices. Advantageously, the blocking compounds of the present disclosure are useful in selective barrier applications and/or selective liner applications. The blocking compounds used advantageously provide reduced electrical penalty compared to leaving behind a layer of organic contaminants.

In one or more embodiments, the blocking compound has a formula of MX_{y}L_{z}, wherein M is a metal selected from the group consisting of ruthenium (Ru), molybdenum (Mo), tungsten (W), copper (Cu), cobalt (Co), nickel (Ni), iridium (Ir), platinum (Pt), palladium (Pd), and osmium (Os), X comprises one or more of substituted or unsubstituted cyclopentadiene, substituted or unsubstituted benzene, substituted or unsubstituted cyclohexadiene, substituted or unsubstituted cycloheptadiene, or substituted or unsubstituted cyclooctadiene, L is a carbon-containing functional group, y is an integer in a range of from 0 to 6, and z is an integer in a range of from 0 to 6. In one or more embodiments where the blocking compound has the formula of MX_{y}L_{z} and y is an integer in the range of from 0 to 6, z is an integer in the range of from 1 to 6. In one or more embodiments where the blocking compound has the formula of MX_{y}L_{z} and z is an integer in the range of from 0 to 6, y is an integer in the range of from 1 to 6. In one or more embodiments, M is tungsten (W) or copper (Cu).

In one or more embodiments, the blocking compound comprises bis(ethylcyclopentadienyl)ruthenium(II) (Ru(EtCp)₂). In one or more embodiments, the blocking compound comprises dimethyldiphenyl molybdenum (Mo(MePh)₂) or diethyldiphenyl molybdenum (Mo(EtPh)₂). In one or more embodiments, the blocking compound comprises one or more of the following compounds:

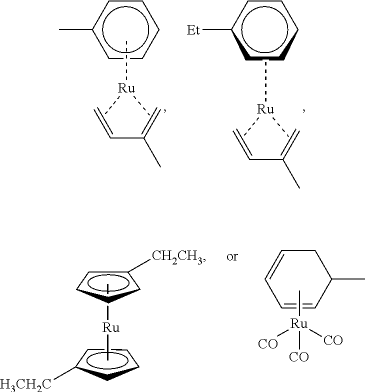

(methylcyclohexadiene tricarbonyl ruthenium). In one or more embodiments, the blocking compound comprises cyclopentadienylcobalt dicarbonyl (CpCo(CO)₂).

In some embodiments, the processing conditions for exposing the substrate 110 to the blocking compound to form the blocking layer 150 may be controlled and may be varied depending on the composition of the blocking compound.

The substrate 110 may be exposed to the blocking compound at any suitable pressure for forming the blocking layer 150. In some embodiments, the substrate 110 is exposed to the blocking compound at a pressure of less than or equal to about 80 Torr, less than or equal to about 70 Torr, less than or equal to about 60 Torr, less than or equal to about 50 Torr, less than or equal to about 40 Torr, less than or equal to about 30 Torr, less than or equal to about 20 Torr, less than or equal to about 15 Torr, less than or equal to about 10 Torr, or less than or equal to about 5 Torr.

The substrate 110 may be exposed to the blocking compound for any suitable time period to form the blocking layer 150 to a predetermined thickness. In some embodiments, the substrate 110 is exposed to the blocking compound for a time period in a range of from 1 second to 600 seconds.

The substrate 110 may be exposed to the blocking compound at any suitable temperature to form the blocking layer 150. In some embodiments, the substrate 110 is exposed to the blocking compound at a temperature in a range of 150° C. to 400° C., such as, for example, in a range of from 200° C. to 300° C.

The blocking layer 150 may be formed using any suitable deposition technique. In one or more embodiments, the blocking layer 150 is formed in an atomic layer deposition (ALD) chamber.

Advantageously, the blocking compounds of the present disclosure are useful in selective barrier applications and/or selective liner applications. Some embodiments of the disclosure are directed to selective barrier applications, e.g., copper barrier applications.

Referring to FIGS. 1A and 1C, at operation 14 of the method 10, the barrier layer 160 is selectively deposited on the sidewalls 148 of the gap 146. In one or more embodiments, the barrier layer 160 has the same properties as the barrier layer 120. In one or more embodiments, the barrier layer 160 does not form on the bottom 149 of the gap 146 due to the presence of the blocking layer 150.

The barrier layer 160 may be selectively deposited using any suitable deposition technique. In one or more embodiments, the barrier layer 160 is selectively deposited by atomic layer deposition (ALD). The barrier layer 160 may have any suitable thickness. In one or more embodiments, the barrier layer 160 has a thickness in a range of from about 2 Å to about 10 Å. In some embodiments, the barrier layer 160 is deposited in a single ALD cycle. In other embodiments, the barrier layer 160 is deposited in from 1 to 20 ALD cycles. In one or more embodiments, each cycle of the 1 to 20 ALD cycles is configured to deposit a thickness of about 0.5 Å of the barrier layer 160.

In one or more embodiments, when the blocking layer 150 is not present, the deposition of the barrier layer 160 is substantially conformal, such that the barrier layer 160 forms on the sidewalls 148 and the bottom 149 of the gap 146. As used herein, a layer which is “substantially conformal” refers to a layer where the thickness is about the same throughout (e.g., on the top, middle and bottom of sidewalls 148 and on the bottom 149 of the gap 146). A layer which is substantially conformal varies in thickness by less than or equal to about 5%, 2%, 1% or 0.5%.

In one or more embodiments, the barrier layer 160 is selectively deposited on a portion of the sidewalls 148 and does not form on the bottom 149 of the gap 146, due to the presence of the blocking layer 150. In one or more embodiments, the barrier layer 160 covers the entirety of the sidewalls 148.

In one or more embodiments, when the barrier layer 160 is formed on the bottom 149 and the sidewalls 148, there is a ratio of the thickness of the barrier layer 160 thickness on the sidewalls 148 to the thickness of the barrier layer 160 thickness on the bottom 149, the ratio being greater than 6. In one or more, the ratio is greater than 5, greater than 4, greater than 3, greater than 2, or greater than 1.

In one or more embodiments, when the blocking layer 150 is present, the barrier layer 160 has a thickness in a range of from 5 Angstroms to 20 Angstroms on the sidewalls 148 and a thickness of less than or equal to 5 Angstroms on the bottom 149. In one or more embodiments, when the blocking layer 150 is present, the barrier layer 160 has a thickness of less than or equal to 4 Angstroms, less than or equal to 3 Angstroms, less than or equal to 2 Angstroms, or less than or equal to 1 Angstrom on the bottom 149. In one or more embodiments, when the blocking layer 150 is present, the barrier layer 160 does not form on the bottom 149.

The barrier layer 160 may comprise any suitable material that prevents copper from diffusing into the dielectric layer 145. Suitable barrier layers for copper barrier applications include, but are not limited to, tantalum nitride (TaN) and manganese nitride (MnN). In some embodiments, the barrier layer 160 comprises tantalum nitride (TaN) formed by atomic layer deposition (ALD). In some embodiments, ALD of the barrier layer 160 comprising tantalum nitride (TaN) includes exposing the substrate 110 to a tantalum-containing precursor, such as, for example, pentakis(dimethylamino)tantalum(V) (PDMAT) and a nitrogen-containing reactant, such as, for example, ammonia (NH₃).

For some copper barrier applications, suitable dopants include, but are not limited to, ruthenium (Ru), copper (Cu), cobalt (Co), manganese (Mn), aluminum (AI), tantalum (Ta), molybdenum (Mo), niobium (Nb), vanadium (V), or combinations thereof. A plasma treatment can be used after doping to promote the intermetallic compound formation between the matrix and dopant, as well as removing film impurities and improving the density of the barrier layer. In other embodiments, post treatment can include, but is not limited to, physical vapor deposition (PVD) treatment, thermal anneal, chemical enhancement, or the like. In some copper barrier applications, a high frequency plasma (defined as greater than about 14 MHz or about 40 MHz or greater) can be used with any inert gas, including, but not limited to, one or more of neon (Ne), hydrogen (H₂), and argon (Ar) gas. In one or more embodiments, to prevent low-K damage, a higher plasma frequency can be used (greater than about 13.56 MHz). In some embodiments, the barrier layer 160 is a copper barrier and comprises tantalum nitride (TaN) doped with ruthenium (Ru).

In selective barrier applications and selective liner applications, the blocking compounds selectively adsorb on the bottom 149 of the gap 146 as the blocking layer 150. The bottom 149 comprises a metallic surface including, but not limited to, copper (Cu), cobalt (Co), tungsten (W), and/or molybdenum (Mo). The blocking compounds advantageously suppress subsequent deposition, e.g., provide nucleation delay on the bottom 149. Advantageously, there is no thermal reaction between the blocking compounds and the tantalum-containing precursor, e.g., pentakis(dimethylamino)tantalum(V) (PDMAT) and the nitrogen-containing reactant, e.g., ammonia (NH₃), used to form the barrier layer 160 comprising tantalum nitride (TaN).

Some embodiments are directed to selective liner applications. Without intending to be bound by theory, in order to maintain as much volume as possible in a subsequent conductive gap 146 fill, scaling down the thickness of the metal liner, e.g., metal liner 170, has become critical to meeting resistivity targets.

Referring to FIGS. 1A and 1D, at operation 15 of the method 10, the metal liner 170 is selectively deposited on the barrier layer 160 of FIG. 1B. In one or more embodiments, the metal liner 170 has the same properties as the metal layer 130. In one or more embodiments, the metal liner 170 is selectively deposited on the sidewalls 148 on the barrier layer 160. In one or more embodiments, the metal liner 170 does not form on the bottom 149 of the gap 146 due to the presence of the blocking layer 150.

It has been found that selectively depositing the metal liner 170 advantageously reduces resistance of a via as compared to resistance of a via in a microelectronic device where a metal liner is not selectively deposited.

In one or more embodiments, the metal liner 170 comprises one or more of ruthenium (Ru), cobalt (cobalt), molybdenum (Mo), or tantalum (Ta). In one or more embodiments, the metal liner 170 comprises one or more of a single layer of ruthenium (Ru) or a single layer of cobalt (Co). In one or more embodiments, the metal liner 170 comprises a single layer of ruthenium (Ru). In one or more embodiments, the metal liner 170 comprises a single layer of cobalt (Co). In one or more embodiments, the metal liner 170 comprises a single layer of ruthenium (Ru) that is selectively deposited on the sidewalls 148 and does not form on the bottom 149 of the gap 146 due to the presence of the blocking layer 150.

In one or more embodiments, when the metal liner 170 comprises a single layer of ruthenium (Ru) selectively deposited on the sidewalls 148 and the blocking layer 150 is formed on the bottom 149, there is a ratio of the thickness of the metal liner thickness on the sidewalls 148 to the thickness of the metal liner 170 thickness on the bottom 149, the ratio being greater than 3. In one or more embodiments, the ratio of the thickness of the metal liner thickness on the sidewalls 148 to the thickness of the metal liner thickness on the bottom 149 is greater than 4, greater than 5, greater than 6 or greater than 7. In one or more embodiments, the metal liner 170 does not form on the bottom 149 due to the presence of the blocking layer 150.

In one or more embodiments, when the metal liner 170 comprises a single layer of selectively deposited ruthenium (Ru), the metal liner 170 has a thickness in a range of from 5 Angstroms to 20 Angstroms on the sidewalls 148. In one or more embodiments, when the metal liner 170 comprises a single layer of selectively deposited ruthenium (Ru), the metal liner 170 has a thickness of less than or equal to 5 Angstroms on the bottom 149. In one or more embodiments, when the metal liner 170 comprises a single layer of selectively deposited ruthenium (Ru), the metal liner 170 has a thickness of less than or equal to 4 Angstroms, less than or equal to 3 Angstroms, less than or equal to 2 Angstroms, or less than or equal to 1 Angstrom on the bottom 149. In one or more embodiments, the metal liner 170 does not form on the bottom 149 due to the presence of the blocking layer 150.

In one or more embodiments, the metal liner 170 comprises a multilayer film having a first liner layer comprised of a first metal and a second liner layer comprised of a second metal. Each of the first metal and the second metal independently comprise one or more of ruthenium (Ru), cobalt (cobalt), molybdenum (Mo), or tantalum (Ta). In one or more embodiments, the first liner layer comprises ruthenium (Ru) and the second liner layer comprises cobalt (Co).

In one or more embodiments, when the metal liner 170 comprises the multilayer film having the first liner layer comprised of the first metal and the second liner layer comprised of the second metal, the multilayer film has a combined thickness in a range of 10 to 20 Angstroms on the sidewalls 148. In one or more embodiments, when the first liner layer comprises ruthenium (Ru) and the second liner layer comprises cobalt (Co), the multilayer film has a combined thickness in a range of 5 to 20 Angstroms on the bottom 149. In one or more embodiments, when the first liner layer comprises ruthenium (Ru) and the second liner layer comprises cobalt (Co), the multilayer film does not form on the bottom 149.

In some embodiments, the multilayer film comprises an alloy of the two metals in a single layer. In one or more embodiments, the multilayer film comprises an alloy of one or more of ruthenium (Ru), cobalt (cobalt), molybdenum (Mo), or tantalum (Ta), such as, for example, an alloy of ruthenium (Ru) and cobalt (cobalt), an alloy of ruthenium (Ru) and molybdenum (Mo), an alloy of ruthenium (Ru) and tantalum (Ta), an alloy of cobalt (cobalt) and molybdenum (Mo), or an alloy of cobalt (Co) and tantalum (Ta).

Advantageously, the multilayer films according to one or more embodiments, which are ultra-thin, e.g., having a thickness of less than or equal to 20 Angstroms, such as in a range of 5 to 20 Angstroms, or in a range of from 10 to 20 Angstroms, provide better interfacial adhesion and mobility between two metals such as between the barrier layer 160 and the metal used to the fill the gap 146. The multilayer films and methods described according to one or more embodiments, can be used in metal contact, interconnect, and capping applications. The multilayer films according to one or more embodiments are thinner than current liners, which are typically greater than 20 Angstroms and up to 30 Angstroms.

The multilayer films described herein can extend the metal fill and capping applications to advanced nodes, such as enabling copper (Cu) reflow in 3 nm node, 2 nm node, 1.4 nm node, and beyond, low resistivity in the middle-of-the line (MOL) and back-end-of-line (BEOL), and memory applications.

The multilayer film can be formed by any suitable deposition techniques and may include one or more deposition techniques. In one or more embodiments, the first liner layer and the second liner layer are formed by the same deposition technique. In one or more embodiments, the first liner layer and the second liner layer are formed by different deposition techniques. The multilayer film can be formed in a single processing chamber or in multiple processing chambers. In one or more embodiments, the multilayer film can be treated by various methods, including thermal treatment, plasma treatment and/or chemical treatment.

In embodiments where the first metal comprises ruthenium (Ru) and the second metal comprises cobalt (Co), the first liner layer is formed by chemical vapor deposition (CVD) including exposing the substrate to

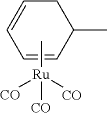

(methylcyclohexadiene tricarbonyl ruthenium) and hydrogen (H₂) followed by CVD of cyclopentadienylcobalt dicarbonyl (CpCo(CO)₂). In selective liner applications, advantageously, there is no thermal reaction between the disclosed blocking compounds and the hydrogen (H₂) used to form the first liner layer comprising ruthenium (Ru).

In specific embodiments, when the first liner layer comprises ruthenium (Ru) and the second liner layer comprises cobalt (Co), the first liner layer and the second liner layer are formed in the same processing chamber. In specific embodiments, when the first liner layer comprises ruthenium (Ru) and the second liner layer comprises cobalt (Co), the first liner layer and the second liner layer are formed in the same chemical vapor deposition (CVD) chamber.

Referring to FIGS. 1A and 1E, at operation 16 of the method 10, the blocking layer 150 is removed. In one or more embodiments, removing the blocking layer 150 comprises a plasma treatment process. The plasma treatment process can be any suitable process. In one or more embodiments, the plasma treatment process includes a physical vapor deposition (PVD) process. In one or more embodiments, the plasma treatment comprises flowing one or more of hydrogen (H₂) or argon (Ar). In one or more embodiments, the plasma treatment process increases a density of the barrier layer 160.

One of the key challenges of organic blocking compounds, for example, is surface contamination after the blocking layer removal step. Due to presence of metal-carbon, metal-nitrogen, and/or metal-oxygen bonding, a layer of organic contaminants may remain on the bottom metal surface, which can be a failure point in electrical tests.

In some embodiments, where L is a carbon-containing functional group in the formula MX_{y}L_{z} of the disclosed blocking compounds, the carbon-containing functional groups are dissociated by the plasma treatment process. Advantageously, the remaining blocking layer 150 after the plasma treatment process is substantially free of carbon (C), which will have reduced electrical penalty compared to leaving behind a layer of organic contaminants.

Referring to FIGS. 1A and 1F, the method 10 includes performing a gap fill process to fill the gap 146 (operation 17). The gap fill process can include any suitable deposition technique. In one or more embodiments, the gap fill process comprises a physical vapor deposition (PVD) process. In one or more embodiments, the gap fill process comprises filling the gap 146 with a gapfill material 180. The gapfill material 180 may include any suitable material, such as a conductive material. In one or more embodiments, the gapfill material 180 comprises one or more of copper (Cu) or cobalt (Co). In one or more embodiments, the gap fill process comprises filling the gap 146 with one or more of copper (Cu) or cobalt (Co) by physical vapor deposition (PVD).

The gapfill material 180 is substantially free of seams and/or voids or free of seams and/or voids. As used in this regard, “substantially free” means that less than about 5%, including less than about 4%, less than about 3%, less than about 2%, less than about 1%, less than about 0.5%, and less than about 0.1% of the total composition of the gapfill material 180 an atomic basis, comprises seams and/or voids. Advantageously, in one or more embodiments, the gapfill material 180 is free of seams and/or voids.

In one or more embodiments, after filling the gap 146 with the gapfill material 180, a completed interconnect structure, e.g., interconnect structure 190 is formed, such that additional interconnect structures may be formed on top of or below the interconnect structure 190.

Referring to FIG. 2A, the method 20 comprises, at operation 21, pre-cleaning a substrate 210. The pre-cleaning process of operation 21 can be any suitable process. In one or more embodiments, the pre-cleaning process of operation 21 can be the same as the pre-cleaning process of operation 11 of method 10.

At operation 22, the method 20 comprises forming a dielectric layer 245 on the substrate 210, e.g., the pre-cleaned substrate. The dielectric layer 245 comprises at least one feature defining a gap 246 having sidewalls 248 and a bottom 249. In some embodiments, the gap 246 defines a via portion 246V and a line portion 246L. At operation 23, the method 20 comprises forming a first blocking layer 250 on the bottom 249 by exposing the substrate 210 to a first blocking compound. At operation 24, the method 20 comprises selectively depositing a barrier layer 260 on the sidewalls 248. At operation 25, the method 20 comprises removing the first blocking layer 250. At operation 26, the method 20 comprises selectively depositing a second blocking layer 255 on the bottom 249. At operation 27, the method 20 comprises selectively depositing a metal liner 270 on the barrier layer 260. At operation 28, the method 20 comprises removing the second blocking layer 255. At operation 29, the method 20 comprises performing a gap fill process to fill the gap 246.

In one or more embodiments, the method 20 comprises operation 21, operation 22, operation 23, operation 24, operation 25, operation 26, operation 27, operation 28, and operation 29. In one or more embodiments, the method 20 consists essentially of operation 21, operation 22, operation 23, operation 24, operation 25, operation 26, operation 27, operation 28, and operation 29. In one or more embodiments, the method 20 consists of operation 23 (where a dielectric layer 245 on a substrate 210, e.g., a pre-cleaned substrate, is provided), operation 24, operation 25, operation 26, operation 27, operation 28, and operation 29.

Referring to FIGS. 2B-2H, a portion of microelectronic device 200 is shown during stages of manufacture. FIG. 2B illustrates the microelectronic device 200 comprising the substrate 210, a barrier layer 220 on the substrate 210, a metal liner 230 on the barrier layer 220, a conductive filled gap 240, an aluminum oxide etch stop layer 242, and the dielectric layer 245 on the aluminum oxide etch stop layer 242. The dielectric layer 245 comprises at least one feature defining a gap 246 having sidewalls 248 and the bottom 249. In one or more embodiments, a first blocking layer 250 is formed on the bottom 249 of the gap 246. It will be appreciated that in one or more embodiments, the conductive filled gap 240 forms a metal line that transfers current within the same device layer.

In one or more embodiments, the features of the microelectronic devices illustrated in FIGS. 1A-1F and FIGS. 2A-2H may have the same properties, including the materials, manufacturing methods, dimensions, etc. In one or more embodiments, the substrate 210, the barrier layer 220 on the substrate 210, the metal liner 230 on the barrier layer 220, the conductive filled gap 240, the aluminum oxide etch stop layer 242, and the dielectric layer 245 on the aluminum oxide etch stop layer 242 have the same properties as the substrate 110, the barrier layer 120, the metal layer 130, the conductive filled gap 140, the aluminum oxide etch stop layer 124, and the dielectric layer 145.

Referring to FIGS. 2A and 2C, at operation 24 of the method 20, the barrier layer 260 is selectively deposited on the sidewalls 248 of the gap 246. The barrier layer 260 may have the same properties as the barrier layer 160 that is selectively deposited according to operation 13 of the method 10.

Referring to FIGS. 2A and 2D, at operation 25 of the method 20, the first blocking layer 250 is removed. The first blocking layer 250 may be removed by the same process as operation 16 of the method 10.

Referring to FIGS. 2A and 2E, at operation 26 of the method 20, a second blocking layer 255 is formed on the bottom 249 of the gap 246. In one or more embodiments, the first blocking layer 250 and the second blocking layer 255 are the same. Stated differently, the first blocking compound used to form the first blocking layer 250 is the same as the second blocking compound used to form the second blocking layer 255. In one or more embodiments, the first blocking layer 250 and the second blocking layer 255 are different. Stated differently, the first blocking compound used to form the first blocking layer 250 is different from the second blocking compound used to form the second blocking layer 255.

Each of the first blocking compound and the second blocking compound independently have a formula of MX_{y}L_{z}, wherein M is a metal selected from the group consisting of ruthenium (Ru), molybdenum (Mo), tungsten (W), copper (Cu), cobalt (Co), nickel (Ni), iridium (Ir), platinum (Pt), palladium (Pd), and osmium (Os), X comprises one or more of substituted or unsubstituted cyclopentadiene, substituted or unsubstituted benzene, substituted or unsubstituted cyclohexadiene, substituted or unsubstituted cycloheptadiene, or substituted or unsubstituted cyclooctadiene, L is a carbon-containing functional group, y is an integer in a range of from 0 to 6, and z is an integer in a range of from 0 to 6.

In one or more embodiments where the first blocking compound and/or the second blocking compound has the formula of MX_{y}L_{z} and y is an integer in the range of from 0 to 6, z is an integer in the range of from 1 to 6. In one or more embodiments where the first blocking compound and/or the second blocking compound has the formula of MX_{y}L_{z} and z is an integer in the range of from 0 to 6, y is an integer in the range of from 1 to 6.

Referring to FIGS. 2A and 2F, at operation 27 of the method 20, a metal liner 270 is selectively deposited on the barrier layer 260. The metal liner 270 may have the same properties as the metal liner 170 that is selectively deposited according to operation 15 of the method 10.

Referring to FIGS. 2A and 2G, at operation 28 of the method 20, the second blocking layer 255 is removed. In one or more embodiments, the first blocking layer 250 and the second blocking layer 255 can be removed by the same process. In one or more embodiments, each of the blocking layer 150, the first blocking layer 250, and the second blocking layer 255 are removed by the same process. In one or more embodiments, each of the blocking layer 150, the first blocking layer 250, and the second blocking layer 255 are removed in accordance with the description referring to operation 16 of the method 10.

Referring to FIG. 2A and FIG. 2G, the method 20 includes performing a gap fill process to fill the gap 246 with a gapfill material 280 (operation 29). The gap fill process can include any suitable deposition technique. In one or more embodiments, the gap fill process of operation 29 is the same as the process of operation 17 of method 10.

In one or more embodiments, after filling the gap 246 with the gapfill material 280, a completed interconnect structure, e.g., interconnect structure 290 is formed, such that additional interconnect structures may be formed on top of or below the interconnect structure 290.

In one or more embodiments, the methods described herein comprise an optional post-processing operation. The optional post-processing operation can be, for example, a process to modify film properties (e.g., annealing) or a further film deposition process (e.g., additional ALD or CVD processes) to grow additional films.

In some embodiments, the optional post-processing operation can be a process that modifies a property of the deposited film/layer. In some embodiments, the optional post-processing operation comprises annealing the substrate. In some embodiments, the annealing process is performed at temperatures in the range of about 300° C., 400° C., 500° C., 600° C., 700° C., 800° C., 900° C. or 1000° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the substrate is annealed for a predetermined time in the range of about 15 seconds to about 90 minutes, or in the range of about 1 minute to about 60 minutes. In some embodiments, annealing the substrate increases the density, decreases the resistivity and/or increases the purity of the layers, such as the barrier layer and/or the metal liner.

In some embodiments, the substrate is moved from a first chamber to a separate, next chamber for further processing. The substrate can be moved directly from the first chamber to the separate processing chamber, or the substrate can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. However, the exact arrangement and combination of chambers may be altered for purposes of performing specific steps of a process as described herein.

Other processing chambers which may be used include, but are not limited to, cyclic deposition including a deposition step, and an annealing or treatment step, atomic layer deposition (ALD), chemical vapor deposition (CVD), physical vapor deposition (PVD), etch, pre-clean, chemical clean, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrates are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc., processes throughout the carousel path.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

Additional embodiments are directed to a cluster tool used to manufacture the microelectronic devices described herein, e.g., microelectronic device 100 and microelectronic device 200, and perform the methods described herein, e.g., method 10 and method 20. In one or more embodiments, the cluster tool comprises a pre-cleaning chamber to pre-clean the substrate and a deposition chamber for forming a dielectric layer including at least one feature defining a gap having sidewalls and a bottom. In one or more embodiments, a pre-cleaned substrate comprising a dielectric layer including at least one feature defining a gap having sidewalls and a bottom is provided.

In one or more embodiments, the cluster tool comprises a deposition chamber for forming a blocking layer, e.g., the blocking layer 150, the first blocking layer 250, and the second blocking layer 255. In one or more embodiments, the cluster tool comprises an atomic layer deposition (ALD) chamber for forming the blocking layer. In one or more embodiments, the cluster tool comprises an atomic layer deposition (ALD) chamber for selectively depositing the barrier layer, e.g., the barrier layer 160 and the barrier layer 260. In one or more embodiments, the cluster tool comprises a chemical vapor deposition (CVD) chamber for selectively depositing the metal liner, e.g., the metal liner 170 and the metal liner 270. In specific embodiments, when the metal liner comprises a multilayer film, the first liner layer and the second liner layer are formed in the same processing chamber. In specific embodiments, the first liner layer and the second liner layer are formed in the same chemical vapor deposition (CVD) chamber.

In one or more embodiments, the cluster tool comprises a chamber for removing the blocking layer. Advantageously, in one or more embodiments, the same processing chamber may be used to selectively deposit the barrier layer and to remove the blocking layer. In one or more embodiments, the cluster tool comprises a deposition chamber for performing the gap fill process to fill the gap. In one or more embodiments, the cluster tool comprises a physical vapor deposition (PVD) chamber for performing the gap fill process to fill the gap.

In one or more embodiments, one or more of the operations of the methods described herein are performed in situ, without an intervening vacuum break. In one or more embodiments, each of the operations of the methods described are performed in situ, without an intervening vacuum break. In one or more embodiments, one or more of the operations of the methods described herein are performed ex situ, such that one or more of the processes are performed with an intervening vacuum break.

Another aspect of the disclosure pertains to a non-transitory computer readable medium including instructions, that, when executed by a controller of a processing system, causes the processing system to perform operations of the methods described herein. In one embodiment, a non-transitory computer readable medium including instructions, that, when executed by a controller of a processing system, causes the processing system to perform operations of the methods described herein with respect to FIGS. 1A-1F and 2A-2H.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents

What is claimed is:

1. A method of manufacturing a microelectronic device, the method comprising:
forming a dielectric layer on a substrate, the dielectric layer including at least one feature defining a gap having sidewalls and a bottom;
forming a blocking layer on the bottom by exposing the substrate to a blocking compound, the blocking compound having a formula of MX_{y}L_{z}, wherein M is a metal selected from the group consisting of ruthenium (Ru), molybdenum (Mo), tungsten (W), copper (Cu), cobalt (Co), nickel (Ni), iridium (Ir), platinum (Pt), palladium (Pd), and osmium (Os), X comprises one or more of substituted or unsubstituted cyclopentadiene, substituted or unsubstituted benzene, substituted or unsubstituted cyclohexadiene, substituted or unsubstituted cycloheptadiene, or substituted or unsubstituted cyclooctadiene, L is a carbon-containing functional group, y is an integer in a range of from 0 to 6, and z is an integer in a range of from 0 to 6;
selectively depositing a barrier layer on the sidewalls;
selectively depositing a metal liner on the barrier layer on the sidewalls;
removing the blocking layer; and
performing a gap fill process to fill the gap.

2. The method of claim 1, wherein the blocking compound comprises bis(ethylcyclopentadienyl)ruthenium(II) (Ru(EtCp)₂).

3. The method of claim 1, wherein the blocking compound comprises dimethyldiphenyl molybdenum (Mo(MePh)₂) or diethyldiphenyl molybdenum (Mo(EtPh)₂).

4. The method of claim 1, wherein the blocking compound comprises

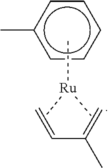

5. The method of claim 1, wherein the blocking compound comprises cyclopentadienylcobalt dicarbonyl (CpCo(CO)₂).

6. The method of claim 1, wherein M is tungsten (W) or copper (Cu).

7. The method of claim 1, wherein the blocking compound comprises a first blocking compound, the first blocking compound used to deposit a first blocking layer.

8. The method of claim 7, further comprising removing the first blocking layer after selectively depositing the barrier layer.

9. The method of claim 8, further comprising forming a second blocking layer on the bottom by exposing the substrate to a second blocking compound.

10. The method of claim 9, wherein the first blocking compound and the second blocking compound are different.

11. The method of claim 9, wherein the first blocking compound and the second blocking compound are the same.

12. The method of claim 1, wherein the barrier layer comprises tantalum nitride (TaN) formed by atomic layer deposition (ALD).

13. The method of claim 1, wherein the metal liner comprises one or more of ruthenium (Ru), cobalt (cobalt), molybdenum (Mo), and tantalum (Ta).

14. The method of claim 13, wherein the metal liner comprises a single layer of ruthenium (Ru).

15. The method of claim 13, wherein the metal liner comprises a multilayer film having a first liner layer comprised of a first metal and a second liner layer comprised of a second metal.

16. The method of claim 15, wherein the first metal comprises ruthenium (Ru) and the second metal comprises cobalt (Co).

17. The method of claim 1, wherein removing the blocking layer comprises a plasma treatment process.

18. The method of claim 17, wherein the plasma treatment process increases a density of the barrier layer.

19. The method of claim 1, wherein the gap fill process comprises filling the gap with a gapfill material comprising one or more of copper (Cu) or cobalt (Co).

20. A method of manufacturing a microelectronic device, the method comprising:
forming a dielectric layer on a substrate, the dielectric layer including at least one feature defining a gap having sidewalls and a bottom;
forming a first blocking layer on the bottom by exposing the substrate to a first blocking compound;
selectively depositing a barrier layer comprising tantalum nitride (TaN) on the sidewalls;
removing the first blocking layer;
forming a second blocking layer on the bottom by exposing the substrate to a second blocking compound;
selectively depositing a metal liner comprising a single layer of ruthenium (Ru) or a multilayer film having a first liner layer comprised of ruthenium (Ru) and a second liner layer comprised of cobalt (Co) on the barrier layer on the sidewalls;
removing the second blocking layer; and
performing a gap fill process comprising filling the gap with a gapfill material comprising one or more of copper (Cu) or cobalt (Co), wherein each of the first blocking compound and the second blocking compound independently have a formula of MX_{y}L_{z}, wherein M is a metal selected from the group consisting of ruthenium (Ru), molybdenum (Mo), tungsten (W), copper (Cu), cobalt (Co), nickel (Ni), iridium (Ir), platinum (Pt), palladium (Pd), and osmium (Os), X comprises one or more of substituted or unsubstituted cyclopentadiene, substituted or unsubstituted benzene, substituted or unsubstituted cyclohexadiene, substituted or unsubstituted cycloheptadiene, or substituted or unsubstituted cyclooctadiene, L is a carbon-containing functional group, y is an integer in a range of from 0 to 6, and z is an integer in a range of from 0 to 6.
